(19) United States
(12) Patent Application Publication
(10) Pub. No.: US 2025/0141182 A1
(43) Pub. Date: May 1, 2025

(54) SEMICONDUCTOR INTEGRATED OPTICAL DEVICE

(71) Applicant: Lumentum Operations LLC, San Jose, CA (US)

(72) Inventors: Takeo KAGEYAMA, Yokohama (JP); Kentaro TANI, Sagamihara (JP)

(21) Appl. No.: 18/622,403

(22) Filed: Mar. 29, 2024

(30) Foreign Application Priority Data
Oct. 31, 2023 (JP) 2023-186412
Jan. 11, 2024 (JP) 2024-002874

(51) Int. Cl. H01S 5/026; H01S 5/042

(52) U.S. Cl. CPC H01S 5/026; H01S 5/04256

(57) ABSTRACT

Provided is a semiconductor integrated optical device with high reliability. The semiconductor integrated optical device includes first and second core layers, a semiconductor layer, a first electrode, and a protrusion portion. The semiconductor integrated optical device includes, in plan view, a BJ joint region in which the protrusion portion is formed, a first optical function device region which is adjacent to the BJ joint region in a predetermined direction and in which the first core layer and the first electrode are located, and a second optical function device region in which the second core layer is located. The first electrode includes a voltage applying end at an end portion on the BJ joint region side on a surface that is in contact with the semiconductor layer. The voltage applying end is placed at a position apart from the BJ joint region in the first optical function device region.

### CROSS-REFERENCE TO RELATED APPLICATIONS

This Patent application claims priority to Japanese patent application number 2024-002874 filed on Jan. 11, 2024 and to Japanese patent application number 2023-186412 filed on Oct. 31, 2023. The disclosure of the prior Applications is considered part of and is incorporated by reference into this Patent Application.

### TECHNICAL FIELD

The present disclosure relates to a semiconductor integrated optical device.

### BACKGROUND

A semiconductor integrated optical device can have a plurality of optical function devices that are integrated. The plurality of optical function devices have semiconductor multilayer structures different from one another. A method for forming different semiconductor multilayer structures on a same substrate in an integrated manner is a butt joint method (hereinafter referred to as “BJ method”). In a BJ portion of a structure, at which two semiconductor multilayer structures are jointed, a part of a substrate forms a side-wall shape control layer between the two semiconductor multilayer structures through a mass transport phenomenon. A semiconductor integrated optical device reduced in deterioration with time is achieved by forming the side-wall shape control layer and thus reducing occurrence of crystal defects of the semiconductor multilayer structures.

### SUMMARY

When a transmission rate in optical communication is increasing, a modulation device, for example, is required to have quick response. An effective way to improve quick response is to reduce capacity of a semiconductor optical device. To that end, it is effective to reduce an area between two electrodes (a p-type electrode and an n-type electrode) of the semiconductor optical device. Price reduction of semiconductor optical devices is advancing as well, and a reduction in device size is an effective way of reducing price. However, a reduction in device size results in a drop in withstand voltage against electrostatic discharge (ESD), and consequently results in a drop in reliability.

Some implementations described herein provide a semiconductor integrated optical device with high reliability.

Some implementations include a semiconductor integrated optical device that comprises: a substrate; a first core layer placed so as to extend in a predetermined direction on the substrate; a second core layer placed on the substrate so as to extend in the predetermined direction and so as to be side by side with the first core layer in the predetermined direction; a second-conductivity type semiconductor layer placed on the first core layer and the second core layer; a first electrode placed on the second-conductivity type semiconductor layer so as to overlap with at least the first core layer; and a protrusion portion of a first conductivity type which protrudes from the substrate toward the first electrode, and which is located between the first core layer and the second core layer to join the first core layer and the second core layer to each other by a butt joint. The semiconductor integrated optical device further includes, in plan view: a BJ joint region in which the protrusion portion is formed; a first optical function device region which is adjacent to the BJ joint region in the predetermined direction, and in which the first core layer and at least a part of the first electrode are located; and a second optical function device region which is adjacent to the BJ joint region on a side opposite from the first optical function device region, and in which the second core layer is located. The first electrode has a voltage applying end in an end portion on the BJ joint region side on a surface that is in contact with the second-conductivity type semiconductor layer. The voltage applying end is placed at a position apart from the BJ joint region in the first optical function device region.

### BRIEF DESCRIPTION OF THE DRAWINGS

FIG. 1 is an example of a top view of a semiconductor integrated optical device according to a first example implementation of the present invention.

FIG. 2 is a schematic sectional view taken along the line II-II of the semiconductor integrated optical device illustrated in FIG. 1.

FIG. 3 is a schematic sectional view taken along the line III-III of the semiconductor integrated optical device illustrated in FIG. 1.

FIG. 4 is an enlarged view of a joint portion in which a semiconductor laser region and a connecting waveguide region are joined to each other in the schematic sectional view of FIG. 2.

FIG. 5 is a graph for showing a relationship of a normalized degree of failure to a positional relationship between a BJ joint region and a voltage applying end, and a relationship of a normalized output power to the positional relationship.

FIG. 6 is an enlarged view of a joint portion in which the connecting waveguide region and a modulator region are joined to each other in the schematic sectional view of FIG. 2.

FIG. 7 is a partial enlarged view of a schematic sectional view taken along the line II-II to illustrate Modification Example 1 of the first example implementation.

FIG. 8 is a partial enlarged view of a schematic sectional view taken along the line II-II to illustrate Modification Example 2 of the first example implementation.

FIG. 9 is an example of a top view of a semiconductor integrated optical device according to a second example implementation of the present invention.

FIG. 10 is an enlarged view of a BJ joint region of the semiconductor integrated optical device illustrated in FIG. 9.

### DETAILED DESCRIPTION

Some implementations are specifically described in detail in the following with reference to drawings. In the drawings, the same members are denoted by the same reference numerals and have the same or equivalent functions, and a repetitive description thereof may be omitted for the sake of simplicity. Note that, the drawings referred to in the following are only for illustrating the example implementations, and are not necessarily drawn to scale.

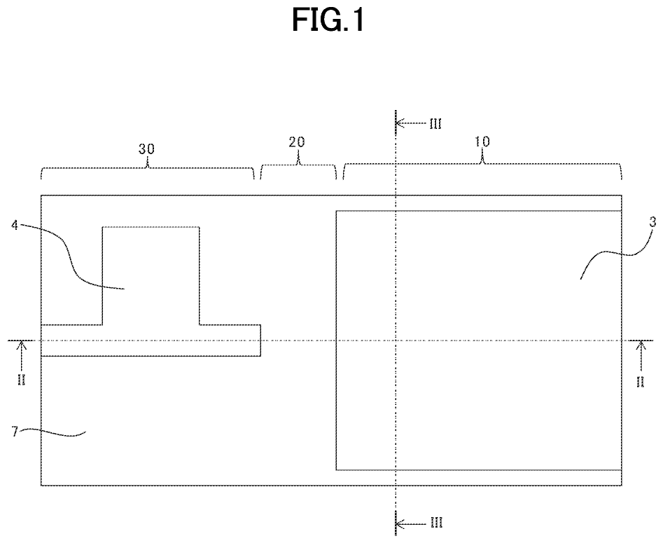

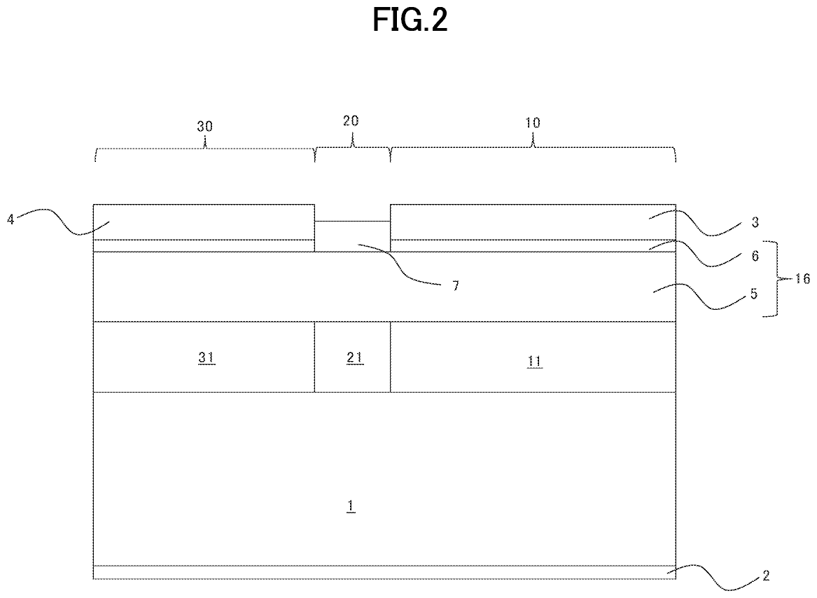

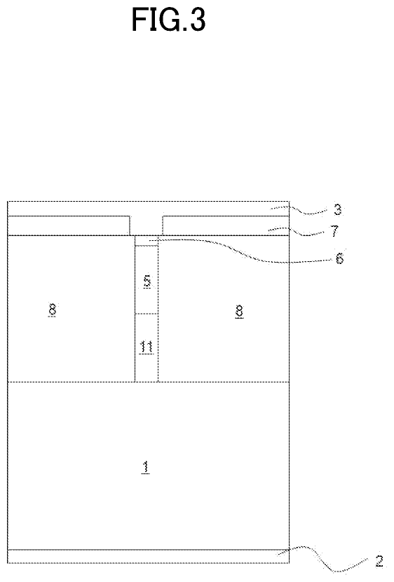

FIG. 1 is a top view of a semiconductor integrated optical device according to a first example implementation of the present invention. FIG. 2 is a schematic sectional view taken along the line II-II of FIG. 1. FIG. 3 is a schematic sectional view taken along the line III-III of FIG. 1. The semiconductor integrated optical device may include, in plan view, a first optical function device region to a third optical function device region to enable three optical function devices integrated on a substrate 1. The three optical function devices may be a semiconductor laser, a connecting waveguide, and a modulator. The region that functions as the semiconductor laser may be hereinafter referred to as “semiconductor laser region 10,” the region that functions as the connecting waveguide may be hereinafter referred to as “connecting waveguide region 20,” and the region that functions as the modulator may be hereinafter referred to as “modulator region 30.” The substrate 1 may be a semiconductor substrate of a first conductivity type, and may be an n-type semiconductor substrate. The semiconductor integrated optical device may have, on a front surface, a first electrode and a second electrode, and may have a counter electrode on a rear surface. Specifically, the semiconductor integrated optical device may have a counter electrode 2 on the rear surface, a semiconductor laser electrode 3 on a front surface of the semiconductor laser region 10, and a modulator electrode 4 on a front surface of the modulator region 30. The counter electrode 2, the semiconductor laser electrode 3, and the modulator electrode 4 may be metal layers. A current may be injected between the semiconductor laser electrode 3 and the counter electrode 2 so that the semiconductor laser region 10 may oscillate and emit continuous light. The continuous light emitted by oscillation may be input to the connecting waveguide region 20 and may propagate to the modulator region 30. An electric signal having a high frequency may be applied between the modulator electrode 4 and the counter electrode 2, and the continuous light may be converted into a high-frequency optical signal having a frequency that varies depending on an applied voltage. The high-frequency optical signal may exit from a facet on the modulator region 30 side. An insulating film 7 may be formed on the front surface of the semiconductor integrated optical device. The counter electrode 2 may be provided for each light function device separately. Although not shown, a low-reflection facet coating film may be formed on the facet on the modulator region 30 side. A high-reflection facet coating film may be formed on a facet on the semiconductor laser region 10 side. Alternatively, a low-reflection facet coating film may be formed on the facet on the semiconductor laser region 10 side as well.

The semiconductor laser region 10 may include a first core layer 11 placed so as to extend in a predetermined direction on the substrate 1. The connecting waveguide region 20 may include a second core layer 21 placed on the substrate 1 so as to extend in the predetermined direction and so as to be side by side with the first core layer 11 in the predetermined direction. The modulator region 30 may include a third core layer 31 placed on the substrate 1 so as to extend in the predetermined direction and so as to be side by side with the second core layer 21 in the predetermined direction. The predetermined direction may be a direction in which a mesa structure described later extends. The first core layer 11 and the second core layer 21 may be joined to each other by a butt joint method (BJ method). A BJ joint region 40 may have a structure in which the first core layer 11 and the second core layer 21 may be joined to each other with a front end of the first core layer 11 and a front end of the second core layer 21 butting against each other. The second core layer 21 and the third core layer 31 may be joined to each other by the BJ method. A second-conductivity type semiconductor layer 16 may be placed on the first core layer 11, the second core layer 21, and the third core layer 31. The second-conductivity type semiconductor layer 16 above the first core layer 11 and the third core layer 31 may include a cladding layer 5 of a second conductivity type and a contact layer 6 of the second conductivity type. The second-conductivity type semiconductor layer 16 above the second core layer 21 may include the cladding layer 5 of the second conductivity type. The cladding layer 5 and the contact layer 6 each may have a structure common to the regions, but may may have a structure varied from one region to another region. The second conductivity type here may be the “p” type. Alternatively, the first conductivity type may be the “p” type, with the second conductivity type set to the “n” type. The second-conductivity type semiconductor layer 16 above the second core layer 21 may not include the contact layer 6 in FIG. 2, but may include the contact layer 6 as in Modification Example 1 described later.

As illustrated in FIG. 3, the semiconductor integrated optical device may be a buried type semiconductor integrated optical device in which both sides of the mesa structure are buried in a semiconductor layer. The first core layer 11, the cladding layer 5, and the contact layer 6 form the mesa structure, and a semiconductor buried layer 8 covers both sides of the mesa structure. The semiconductor buried layer 8 here may be a semi-insulating semiconductor layer or a multilayer structure including a p-type semiconductor layer and an n-type semiconductor layer. The structure of FIG. 3 may be substantially the same in the connecting waveguide region 20 and the modulator region 30. The semiconductor integrated optical device may be of a ridge type in which each core layer does not have a mesa structure.

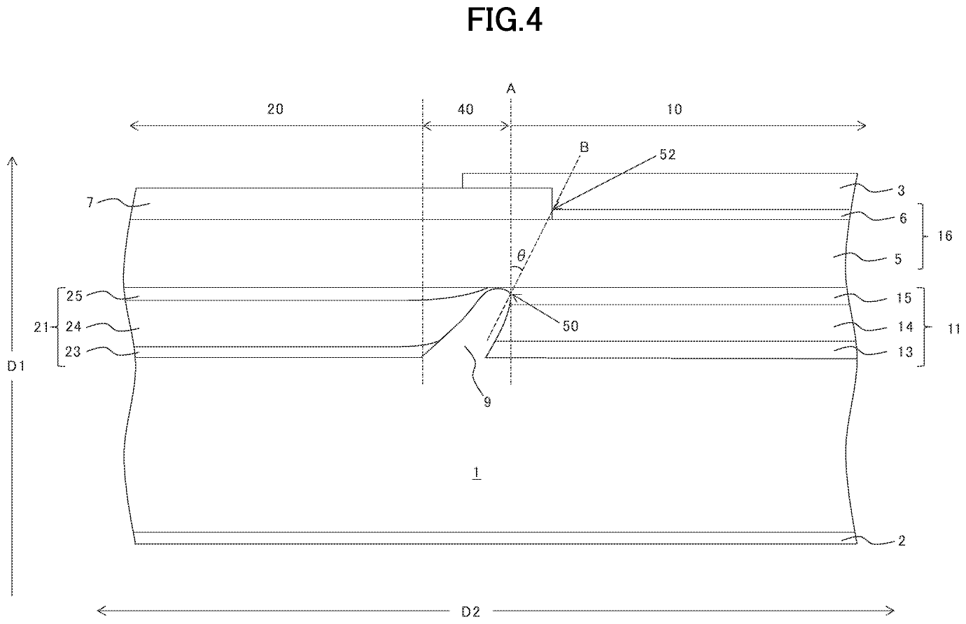

FIG. 4 is an enlarged view of a joint portion in which the semiconductor laser region 10 and the connecting waveguide region 20 are joined to each other. The first core layer 11 of the semiconductor laser region 10 and the second core layer 21 of the connecting waveguide region 20 may be joined to each other by a BJ.

The first core layer 11 may include a first lower optical confinement layer (hereinafter referred to as “first lower SCH layer”) 13, an active layer 14, and a first upper SCH layer 15. The first lower SCH layer 13 may be of the same conductivity type as the conductivity type of the substrate 1 and, here, may be an n-type layer. The active layer 14 may be a multiple quantum well layer (hereinafter referred to as “MQW layer”), and may be an i-type semiconductor layer which contains no intentionally added impurities. The first upper SCH layer 15 may be of the same conductivity type as the conductivity type of the cladding layer 5 and, here, may be a p-type semiconductor layer. Although not shown, a grating layer may be included between the first upper SCH layer 15 and the cladding layer 5. The semiconductor laser region 10 may be set so as to oscillate and emit light in a wavelength band of 1.3 micrometers (μm) to 1.55 μm. The grating layer may be located between the substrate 1 and the first lower SCH layer 13. The semiconductor layers given here are merely an example, and other layers may be included. The first lower SCH layer 13 and the first upper SCH layer 15 may be i-type semiconductor layers which contain no intentionally added impurities.

The second core layer 21 may include a second lower optical confinement layer (hereinafter referred to as “second lower SCH layer”) 23, a waveguide layer 24, and a second upper SCH layer 25. The second lower SCH layer 23 may be of the same conductivity type as the conductivity type of the substrate 1 and, here, may be an n-type layer. The waveguide layer 24 may be a bulk semiconductor layer, and may be an i-type semiconductor layer which contains no intentionally added impurities. The second upper SCH layer 25 may be of the same conductivity type as the conductivity type of the cladding layer 5 and, here, may be a p-type semiconductor layer. The semiconductor layers given here are merely an example, and other layers may be included. The second lower SCH layer 23 and the second upper SCH layer 25 may be i-type semiconductor layers which contain no intentionally added impurities.

A protrusion portion 9 may be provided in a part of a space between the first core layer 11 and the second core layer 21. The protrusion portion 9 may be of the first conductivity type, may protrudes from the substrate 1 toward the semiconductor laser electrode 3, and may be located between the first core layer 11 and the second core layer 21 to join the first core layer 11 and the second core layer 21 to each other by a butt joint. A drop in optical coupling ratio in the BJ joint region 40 may be reduced by the protrusion portion 9. Specifically, the protrusion portion 9 may be formed unitarily with an underlying semiconductor layer, and may have a shape slanted toward the semiconductor laser region 10. The underlying semiconductor layer here may be the substrate 1. Accordingly, the protrusion portion 9 may be the same n-type semiconductor layer as the substrate 1, and may be formed from the same material as the material of the substrate 1. In the first example implementation, the substrate 1 and the protrusion portion 9 may be an n-type InP layer. There may be a case in which a buffer layer may be formed between the substrate 1 and the first core layer 11 and the second core layer 21 from a material of the same conductivity type as the conductivity type of the substrate 1 that differs from, or is the same as, the material of the substrate 1. In this case, the buffer layer may be the underlying semiconductor layer. The protrusion portion 9 may be formed when or before the second core layer 21 is grown, by recrystallization of a part of the underlying semiconductor layer along a side wall of the first core layer 11 through a mass transport phenomenon. The protrusion portion 9 may cover the entirety of the joint portion in which the first core layer 11 and the second core layer 21 are joined to each other. The second core layer 21 in and around the BJ joint region 40 may have a shape that may be overall slanted along the protrusion portion 9. In the first example implementation, the protrusion portion 9 may be formed slanted toward the semiconductor laser region 10 because the second core layer 21 is formed after the first core layer 11 is formed. In a case in which the second core layer 21 is formed first, the protrusion portion 9 slants toward the connecting waveguide region 20. Although a top surface of the first core layer 11 (a top surface of the first upper SCH layer 15) and a top surface of the second core layer 21 (a top surface of the second upper SCH layer 25) may be flush with each other in FIG. 4, there may be a level difference therebetween. The second core layer 21 in the BJ joint region 40 may bulge toward the cladding layer 5 past a height of the top surface of the second upper SCH layer 25 in the connecting waveguide region 20.

When viewed from a direction in which the semiconductor layers may be grown (hereinafter referred to as “first direction D1”), the protrusion portion 9 may be formed so that a front end of the protrusion portion 9 reaches a position past a top surface of the active layer 14. That is, the front end reaches halfway through the first upper SCH layer 15. In the present application, a region in which the protrusion portion 9 protrudes from the underlying semiconductor layer (substrate 1) (that is, a region in which the protrusion portion 9 may be formed) may be defined as the BJ joint region 40. As illustrated in FIG. 4, the protrusion portion 9 starts to rise from the underlying semiconductor layer at an end portion of the BJ joint region 40 on the connecting waveguide region 20 side. Meanwhile, at an end portion of the BJ joint region 40 on the semiconductor laser region 10 side, the protrusion portion 9 protrudes most (a side portion end 50) toward the first core layer 11 in a direction in which the mesa structure extends (hereinafter referred to as “second direction D2”), instead of starting to rise from the underlying semiconductor layer. The side portion end 50 does not coincide with the front end, which may be the highest part of the protrusion portion 9 in the direction in which the semiconductor layers are grown.

As illustrated in FIG. 4, the semiconductor laser electrode 3 may be placed on the second-conductivity type semiconductor layer 16 so as to overlap with at least the first core layer 11. The semiconductor laser electrode 3 accordingly may have a voltage applying end 52 at which the semiconductor laser electrode 3 and the second-conductivity type semiconductor layer 16 (here, a top surface of the contact layer 6) may be in contact with each other around the BJ joint region 40. In other words, the semiconductor laser electrode 3 may have the voltage applying end 52 in an end portion on the BJ joint region 40 side on a surface that may be in contact with the second-conductivity type semiconductor layer 16. The voltage applying end 52 may be a site at which the electrode and the second-conductivity type semiconductor layer may be in contact with each other, and may be closest in position to the BJ joint region 40. The semiconductor laser electrode 3 may overlap with a part of the BJ joint region 40 in plan view, but a region to which a voltage is applied during actual voltage application may be a region in which the semiconductor laser electrode 3 and the contact layer 6 are in contact with each other. The voltage applying end 52 may be placed at a position apart from the protrusion portion 9 in a direction of travel away from the BJ joint region 40 toward the semiconductor laser region 10. In other words, the voltage applying end 52 may be placed so as to avoid the BJ joint region 40.

As described above, the semiconductor integrated optical device according to the present disclosure may include, in plan view: the BJ joint region 40, which may be an area with the protrusion portion 9 formed therein; the first optical function device region (semiconductor laser region 10), which may be adjacent to the BJ joint region 40 in the predetermined direction and in which the first core layer 11 and at least a part of the first electrode (semiconductor laser electrode 3) may be located; and the second optical function device region (connecting waveguide region 20), which may be adjacent to the BJ joint region 40 on a side opposite from the first optical function device region and in which the second core layer 21 may be located. According to this configuration, the voltage applying end 52 may be provided in the first optical function device region at a position apart from the BJ joint region 40. That the voltage applying end 52 may be apart from the protrusion portion 9 may be rephrased as no voltage being applied to a part of the first core layer 11 on the BJ joint region 40 side. In a semiconductor laser, a region to which no voltage is applied functions so as to absorb light, and this may be unfavorable as characteristics of a semiconductor laser. Accordingly, the voltage applying end (a front end of a contact layer) may be placed in a region that overlaps with the protrusion portion 9. However, crystals around the BJ joint region 40 may deteriorate first (e.g., as may be indicated by a test to check an electrostatic discharge (ESD) withstand voltage in the structure). This may be due to the following mechanism. A voltage applied to the semiconductor laser electrode 3 is transmitted via the contact layer 6 to the cladding layer 5. The voltage is applied to the first core layer 11 but, because the protrusion portion 9 which is the n-type semiconductor layer extends to the p-type layer (first upper SCH layer 15), an electric field concentrates in a region in which the protrusion portion 9 and the first core layer 11 are in contact with each other. As a result, deterioration of crystals has been caused by ESD around the protrusion portion 9, that is, around the BJ joint region 40. A crystal quality around the BJ joint region 40 may be poor compared to sites apart from the BJ joint region 40, and the poor crystal quality may be another reason for the tendency toward deterioration around the BJ joint region 40. The semiconductor integrated optical device according to the first example implementation can reduce the concentration of the electric field at the protrusion portion 9 because the voltage applying end 52 may be distanced from the protrusion portion 9, and can accordingly improve the withstand voltage against ESD.

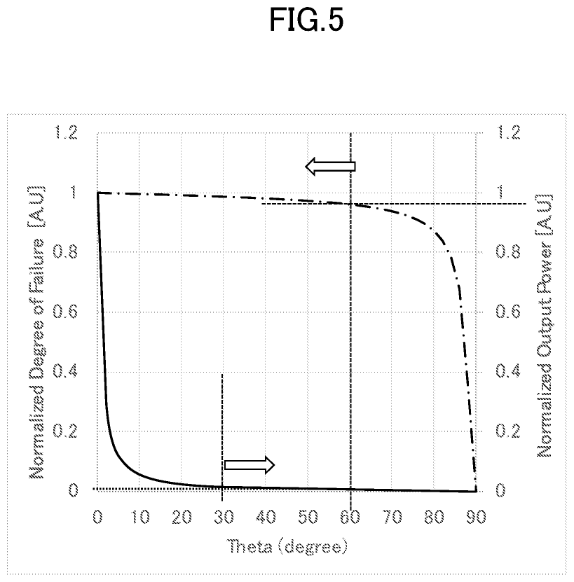

In order to improve the withstand voltage against ESD, the voltage applying end 52 may be preferred to be as far away from the protrusion portion 9 as possible. However, when the voltage applying end 52 may be too far from the protrusion portion 9, a region of the first core layer 11 to which no voltage may be applied expands, and characteristics as a semiconductor laser consequently deteriorate. A line extended in the first direction D1 with the side portion end 50 of the protrusion portion 9 as a start point (a line running through the side portion end 50 in a normal line direction of the substrate 1) may be defined as a first virtual line A. A line running through the side portion end 50 and a part of the voltage applying end 52 that may be closest to the substrate 1 in sectional view may be defined as a second virtual line B. When an angle formed by the first virtual line A and the second virtual line B is represented by θ, a relationship of a normalized degree of failure due to ESD to θ and a relationship of a normalized output power to θ are shown in FIG. 5. An axis of abscissa of FIG. 5 indicates the angle θ formed by the first virtual line A and the second virtual line B illustrated in FIG. 4. An axis of ordinate on the left hand side indicates the degree of failure in an ESD test that is normalized. A value “1” on the axis of ordinate does not indicate a 100% of failure. The value “1” on the axis of ordinate indicates that the degree of failure that has occurred in an ESD test conducted under predetermined conditions has been a reference degree of failure. The relationship between θ and the normalized degree of failure is represented by a solid line graph, and the degree of failure rapidly drops as θ increases. When θ is 30° or more, the semiconductor integrated optical device is satisfactorily fit for practical use. The angle θ is more preferably 45° or more. An axis of ordinate on the right hand side indicates a normalized output power. A dot-dash line represents a relationship between θ and an output power with 1 indicating the output power that is observed when a voltage is applied (a current is injected) to the entire first core layer 11. In order to obtain an output power of 95% or higher, θ is preferred to be 60° or less. To express a preferred positional relationship between the voltage applying end 52 and the side portion end 50 of the protrusion portion 9 with use of a distance in the second direction D2, the distance between the voltage applying end 52 and the side portion end 50 of the protrusion portion 9 may be preferred to be 1 μm or more and 10 μm or less. A preferred distance between the voltage applying end 52 and the side portion end 50 of the protrusion portion 9 that takes variation in manufacturing process and other factors into consideration may be 3 μm or more.

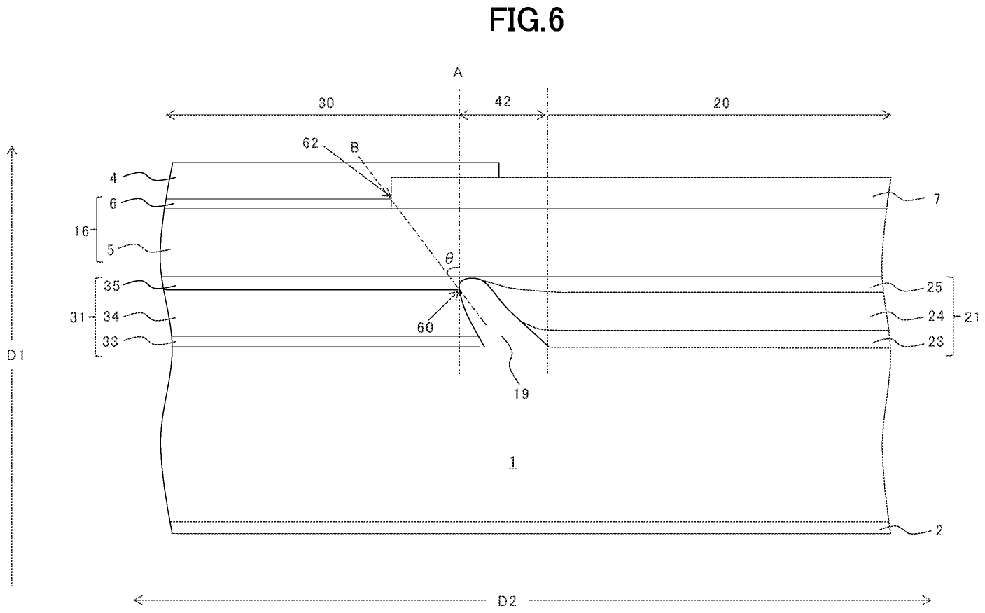

FIG. 6 is an enlarged view around a joint portion in which the connecting waveguide region 20 and the modulator region 30 are joined to each other. The second core layer 21 of the connecting waveguide region 20 and the third core layer 31 of the modulator region 30 may be joined by a BJ. A region between the connecting waveguide region 20 and the modulator region 30 is hereinafter referred to as “second BJ joint region 42.”

The third core layer 31 may include a third lower SCH layer 33, an absorption layer 34, and a third upper SCH layer 35. The third lower SCH layer 33 may be of the same conductivity type as the conductivity type of the substrate 1. Here, the third lower SCH layer 33 may be an n-type layer. The absorption layer 34 may be an MQW layer, and may be an i-type semiconductor layer that contains no intentionally added impurities. The third upper SCH layer 35 may be of the same conductivity type as the conductivity type of the cladding layer 5 and, here, may be a p-type semiconductor layer. The modulator region 30 may be an optical function device that converts light emitted from the semiconductor laser region 10 by oscillation into a high-frequency optical signal. The semiconductor layers given here may be merely an example, and other layers may be included. The third lower SCH layer 33 and the third upper SCH layer 35 may be i-type semiconductor layers which contain no intentionally added impurities.

A second protrusion portion 19 may be provided in a part of a space between the second core layer 21 and the third core layer 31. The second protrusion portion 19 may be of the first conductivity type, protrudes from the substrate 1 toward the modulator electrode 4, and may be located between the second core layer 21 and the third core layer 31 to join the second core layer 21 and the third core layer 31 to each other by a butt joint. Specifically, the second protrusion portion 19 may be formed unitarily with an underlying semiconductor layer, and may have a shape slanted toward the modulator region 30. The underlying semiconductor layer here may be the substrate 1. Accordingly, the second protrusion portion 19 may be the same n-type semiconductor layer as the substrate 1, and may be formed from the same material as the material of the substrate 1. In the first example implementation, the second protrusion portion 19 may be an n-type InP layer. There may be a case in which a buffer layer may be formed between the substrate 1 and the second core layer 21 and the third core layer 31 from a material of the same conductivity type as the conductivity type of the substrate 1 that differs from, or may be the same as, the material of the substrate 1. In this case, the buffer layer may be the underlying semiconductor layer. The second core layer 21 in and around the second BJ joint region 42 may have a shape that may be overall slanted along the second protrusion portion 19. In the first example implementation, the second protrusion portion 19 may be formed slanted toward the modulator region 30 because the second core layer 21 is formed after the third core layer 31 is formed. In a case in which the second core layer 21 is formed first, the second protrusion portion 19 slants toward the connecting waveguide region 20. Although the top surface of the second core layer 21 (the top surface of the second upper SCH layer 25) and a top surface of the third core layer 31 (a top surface of the third upper SCH layer 35) may be flush with each other in FIG. 6, there may be a level difference therebetween. The second core layer 21 in and around the second BJ joint region 42 may bulge toward the cladding layer 5 so that the top surface of the second core layer 21 exceeds a height of the top surface of the third upper SCH layer 35 of the modulator region 30.

When viewed from the first direction D1, the second protrusion portion 19 may be formed so that a front end of the second protrusion portion 19 reaches a position past the absorption layer 34. That is, the front end reaches halfway through the third upper SCH layer 35. In the present application, as in FIG. 4, a region in which the second protrusion portion 19 protrudes from the underlying semiconductor layer (substrate 1) may be defined as the second BJ joint region 42. As illustrated in FIG. 6, at an end portion of the second BJ joint region 42 on the modulator region 30 side, the second protrusion portion 19 protrudes most (a side portion end 60) toward the third core layer 31 in the second direction D2. Meanwhile, at an end portion of the second BJ joint region 42 on the connecting waveguide region 20 side, the second protrusion portion 19 starts to rise from the underlying semiconductor layer. That is, a side portion end of a protrusion portion means an end portion that may be in contact with a semiconductor layer (core layer) adjacent to the protrusion portion in the second direction D2, and that protrudes most to the core layer. A region between such an end portion on the left hand side and such an end portion on the right hand side may be defined as a BJ joint region.

The modulator electrode 4 may be placed on the second-conductivity type semiconductor layer 16 so as to overlap with at least the third core layer 31. The modulator region 30 accordingly may have a second voltage applying end 62 at which the modulator electrode 4 and the second-conductivity type semiconductor layer 16 (here, the top surface of the contact layer 6) may be in contact with each other around the second BJ joint region 42. In other words, the modulator electrode 4 may have the second voltage applying end 62 in an end portion on the second BJ joint region 42 side on a surface that is in contact with the second-conductivity type semiconductor layer 16. The second voltage applying end 62 may be a site at which the electrode and the second-conductivity type semiconductor layer are in contact with each other, and may be closest in position to the second BJ joint region 42. The modulator electrode 4 may overlap with a part of the second BJ joint region 42, but a region to which a voltage is applied during actual voltage application may be a region in which the contact layer 6 is placed. The second voltage applying end 62 may be placed at a position apart from the second protrusion portion 19 in a direction of travel away from the second BJ joint region 42.

As described above, according to the present disclosure, the semiconductor integrated optical device may include, in plan view: the second BJ joint region 42 as a region which may be adjacent to the second optical function device (connecting waveguide region 20) in the predetermined direction and in which the second protrusion portion 19 may be formed; and the third optical function device region (modulator region 30) which may be adjacent to the second BJ joint region 42 on a side opposite from the second optical function device region and in which the third core layer 31 may be located. The second voltage applying end 62 may be provided in the third optical function device region (modulator region 30) at a position apart from the second BJ joint region 42. Accordingly, as in the BJ joint region 40 joining the semiconductor laser region 10 and the connecting waveguide region 20 to each other, the second voltage applying end 62 of the modulator region 30 may be distanced from the second protrusion portion 19. Concentration of an electric field around the second BJ joint region 42 can consequently be reduced when a voltage is applied to the modulator region 30. As in FIG. 4, θ represents an angle between the first virtual line A extended in the first direction D1 with the side portion end 60 of the second protrusion portion 19 as a start point and the second virtual line B connecting the side portion end 60 and the second voltage applying end 62 to each other. In this case, when the axis of ordinate on the right hand side of FIG. 5 indicates a normalized absorption amount, FIG. 5 may be read as a relationship of the normalized degree of failure to θ and a relationship of the normalized absorption amount to θ in the modulator region 30. That is, in order to reduce the degree of failure due to ESD, θ may be preferred to be 30° or more, more preferably 45° or more. Meanwhile, in order to maintain characteristics as a modulator, θ may be preferred to be 60° or less. Strictly speaking, a position of an intersecting point between the first virtual line A and the second virtual line B in the semiconductor laser region 10 and a position of an intersecting point between the first virtual line A and the second virtual line B in the modulator region 30 differ from each other in the first direction D1. However, the difference thereof in actual dimensions may be on the order of nm, which may be very small. Meanwhile, distances of the voltage applying ends 52 and 62 to the first virtual line A may be each on the order of μm, and there may be accordingly no problem in applying FIG. 5 to the modulator region 30.

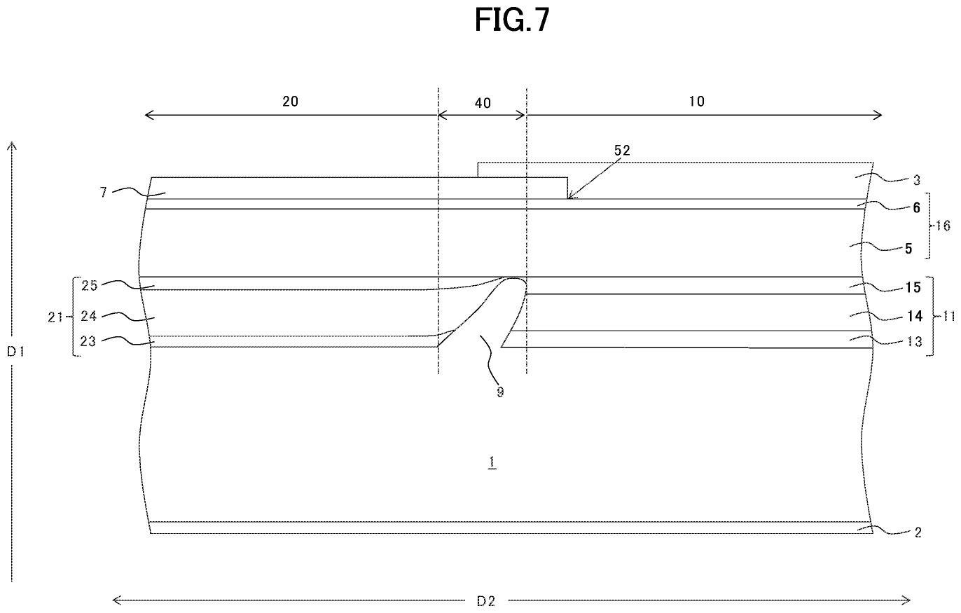

FIG. 7 is a schematic sectional view taken along the line II-II to illustrate regions around the BJ joint region 40 of a semiconductor integrated optical device according to Modification Example 1 of the first example implementation. Modification Example 1 differs from the first example implementation in that the contact layer 6 may be placed so as to spread wide from the semiconductor laser region 10 to the connecting waveguide region 20. In Modification Example 1, as in the first example implementation, the voltage applying end 52 may be an end position of a region in which an electrode (the semiconductor laser electrode 3) and a second-conductivity type semiconductor layer (the contact layer 6) may be in contact with each other, on the BJ joint region 40 side. A structure similar to this may be employed also in the second BJ joint region 42 in which the connecting waveguide region 20 and the modulator region 30 are joined to each other.

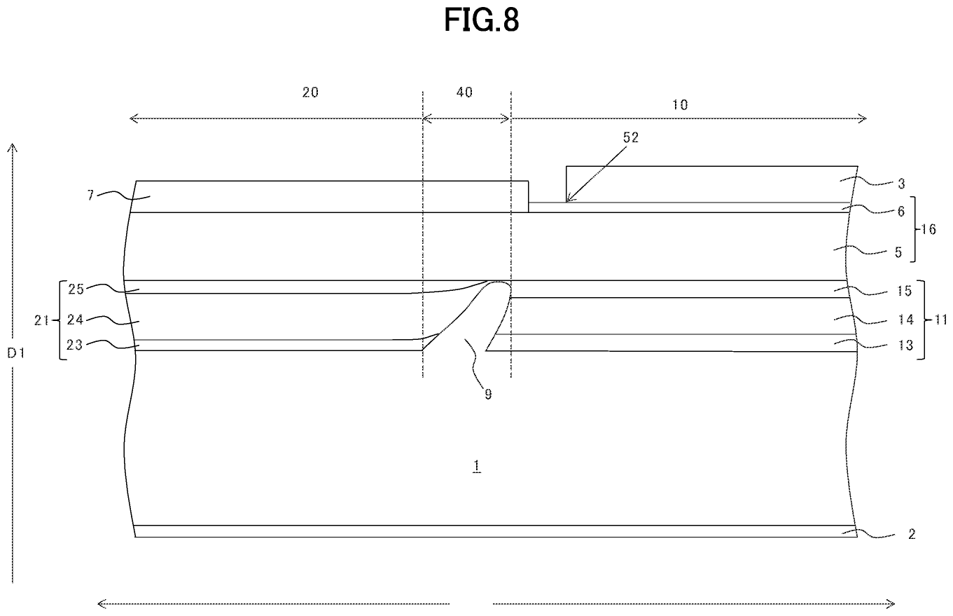

FIG. 8 is a schematic sectional view taken along the line II-II to illustrate regions around the BJ joint region 40 of a semiconductor integrated optical device according to Modification Example 2 of the first example implementation. Modification Example 2 differs from the first example implementation in that an end portion of the semiconductor laser electrode 3 may be placed at a position distanced from the BJ joint region 40, instead of overlapping with the BJ joint region 40. In Modification Example 2, the voltage applying end 52 may be a place at which the end portion of the semiconductor laser electrode 3 and the contact layer 6 may be in contact with each other. Although every electrode may be in contact with the contact layer 6 in the descriptions given up to this point, the contact layer 6 may be omitted so that an electrode is in direct contact with the cladding layer 5. In this case, a front end of a site at which the electrode and the cladding layer 5 are connected to each other may be a voltage applying end. A structure similar to this may be employed also in the second BJ joint region 42 in which the connecting waveguide region 20 and the modulator region 30 are joined to each other.

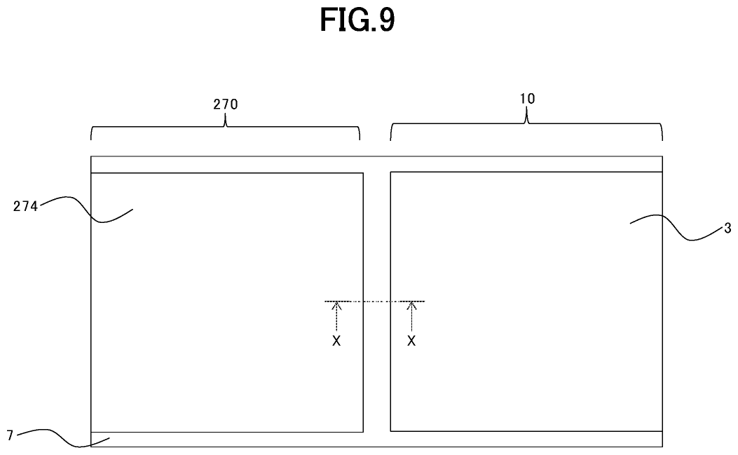

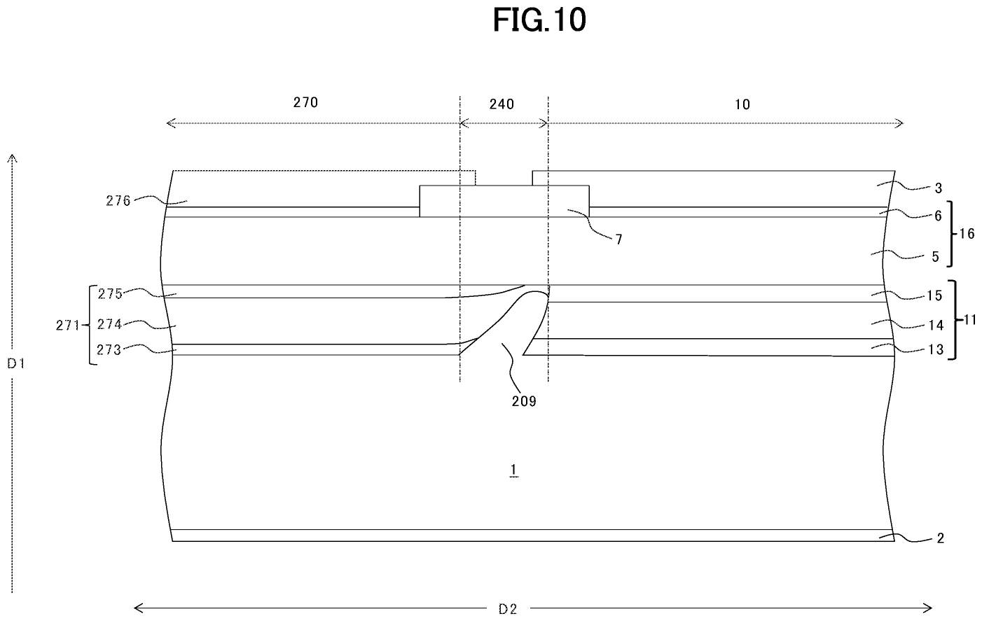

FIG. 9 is a top view of a semiconductor integrated optical device according to a second example implementation of the present invention. FIG. 10 is a schematic sectional view taken along the line X-X of FIG. 9. The semiconductor integrated optical device of the second example implementation integrates the semiconductor laser region 10 and an optical amplification region 270 on the substrate 1. That is, the semiconductor integrated optical device of the second example implementation may be a semiconductor integrated optical device in which two optical function devices are integrated. The semiconductor laser region 10 may have the same structure as that given in the first example implementation.

The optical amplification region 270 may have a function of amplifying light emitted from the semiconductor laser region 10. The optical amplification region 270 may include a second core layer 271. The second core layer 271 may include a second lower SCH layer 273, an active layer 274, and a second upper SCH layer 275. The second lower SCH layer 273 may be of the first conductivity type and the second upper SCH layer 275 may be of the second conductivity type. The active layer 274 may be an MQW layer. The optical amplification region 270 may include an optical amplification electrode 276. The semiconductor layers given here may be merely an example, and other layers may be included. The second lower SCH layer 273 and the second upper SCH layer 275 may be i-type semiconductor layers which contain no intentionally added impurities.

The first core layer 11 and the second core layer 271 may be joined to each other by a BJ in a BJ joint region 240, which may include a protrusion portion 209. A front end of the protrusion portion 209 in the first direction D1 reaches past the active layer 14. In the second example implementation, as in the first example implementation, the voltage applying end of the semiconductor laser region 10 and a voltage applying end of the optical amplification region 270 may be placed apart from the BJ joint region 240.

In the example implementations described above, the substrate may be a conductive substrate, but is not limited thereto. An insulating (including semi-insulating) substrate may also be used. In a case of using an insulating substrate, a first-conductivity type semiconductor layer may be placed in a lowermost layer, and a conductivity type of the protrusion portion may be the same as the conductivity type of the semiconductor layer. A counter electrode may be placed on a surface on which the core layers may be formed, instead of on a rear side of the substrate.

The present invention gives high reliability to a semiconductor integrated optical device in which a plurality of optical function devices may be integrated on a substrate. A protrusion portion may be provided in a joint portion in which respective core layers of two optical function devices may be joined to each other. A voltage applying end at which an electrode and the semiconductor layer may be in contact with each other may be distanced from a side portion end at which the protrusion portion may be in contact with one of the core layers in a direction in which light is traveled (the second direction D2), to thereby reduce concentration of an electric field to a BJ joint region. High reliability is thus obtained. The protrusion portion may be of the first conductivity type. The present invention may be effective particularly for a structure in which a front end of the protrusion portion is at a position that reaches past an MQW layer in a direction of growth of semiconductors (the first direction D1) and that is close to a second-conductivity type semiconductor layer. When θ represents an angle between the first virtual line A extended in the first direction with the side portion end of the protrusion portion as a start point and the second virtual line B connecting the side portion end of the protrusion portion and the voltage applying end to each other, θ may be preferred to be 30° or more, more preferably 45° or more. The angle θ may be also preferred to be 60° or less.

While there have been described what are at present considered to be certain embodiments of the invention, it will be understood that various modifications may be made thereto, and it is intended that the appended claims cover all such modifications as fall within the true spirit and scope of the invention.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A semiconductor integrated optical device, comprising:
a substrate;
a first core layer placed so as to extend in a predetermined direction on the substrate;
a second core layer placed on the substrate so as to extend in the predetermined direction and so as to be side by side with the first core layer in the predetermined direction;
a second-conductivity type semiconductor layer placed on the first core layer and the second core layer;
a first electrode placed on the second-conductivity type semiconductor layer so as to overlap with at least the first core layer; and
a protrusion portion of a first conductivity type which protrudes from the substrate toward the first electrode, and which is located between the first core layer and the second core layer to join the first core layer and the second core layer to each other by a butt joint,
the semiconductor integrated optical device further comprising, in plan view:
a BJ joint region in which the protrusion portion is formed;
a first optical function device region which is adjacent to the BJ joint region in the predetermined direction, and in which the first core layer and at least a part of the first electrode are located; and
a second optical function device region which is adjacent to the BJ joint region on a side opposite from the first optical function device region, and in which the second core layer is located,
wherein the first electrode has a voltage applying end in an end portion on the BJ joint region side on a surface that is in contact with the second-conductivity type semiconductor layer, and
wherein the voltage applying end is placed at a position apart from the BJ joint region in the first optical function device region.

2. The semiconductor integrated optical device according to claim 1,
wherein the protrusion portion has a side portion end which is in contact with the first core layer in a sectional view and which is closest in position to the first core layer side, and
wherein, when a line that runs along a normal line direction of the substrate through the side portion end is defined as a first virtual line, a line that runs through the side end portion and the voltage applying end closest to the substrate in a sectional view is defined as a second virtual line, and an angle formed by the first virtual line and the second virtual line is represented by θ, the angle θ is 30° or more and 60° or less.

3. The semiconductor integrated optical device according to claim 2, wherein the angle θ is 45° or more.

4. The semiconductor integrated optical device according to claim 1,
wherein the first core layer includes an active layer, and
wherein a front end of the protrusion portion in a normal line direction of the substrate is located above a top surface of the active layer.

5. The semiconductor integrated optical device according to claim 1,
wherein the first core layer includes an optical confinement layer of a second conductivity type, and
wherein a front end of the protrusion portion in a normal line direction of the substrate is in contact with the optical confinement layer.

6. The semiconductor integrated optical device according to claim 1,
wherein the second-conductivity type semiconductor layer includes a contact layer of a second conductivity type, and
wherein the voltage applying end is a contact point at which the first electrode and the contact layer of the second conductivity type are in contact with each other.

7. The semiconductor integrated optical device according to claim 1,
wherein the protrusion portion includes a side portion end which is in contact with the first core layer and which is closest in position to the first core layer side, and another side portion end which is in contact with the second core layer and which is closest in position to the second core layer side, and
wherein the BJ joint region is defined by a region sandwiched between the side portion end and the another side portion end.

8. The semiconductor integrated optical device according to claim 1, further comprising:
a third core layer placed on the substrate so as to extend in the predetermined direction and so as to be side by side with the second core layer in the predetermined direction;
a second electrode placed on the second-conductivity type semiconductor layer so as to overlap with at least the third core layer; and
a second protrusion portion of the first conductivity type which protrudes from the substrate toward the second electrode, and which is located between the second core layer and the third core layer to join the second core layer and the third core layer to each other by a butt joint,
the semiconductor integrated optical device further comprising, in plan view:
a second BJ joint region which is adjacent to the second optical function device region in the predetermined direction, and in which the second protrusion portion is formed; and
a third optical function device region which is adjacent to the second BJ joint region on a side opposite from the second optical function device region, and in which the third core layer is located,
wherein the second electrode includes a second voltage applying end at an end portion on the second BJ joint region side on a surface that is in contact with the second-conductivity type semiconductor layer, and
wherein the second voltage applying end is provided at a position apart from the second BJ joint region in the third optical function device region.

9. The semiconductor integrated optical device according to claim 1,
wherein a part of the first electrode is placed in the BJ joint region, and
wherein, in the BJ joint region, an insulating film is placed between the first electrode and the second-conductivity type semiconductor layer.

10. The semiconductor integrated optical device according to claim 1, wherein the substrate is a first-conductivity type semiconductor substrate.

11. The semiconductor integrated optical device according to claim 10, further comprising a counter electrode on a surface opposite from a surface of the substrate on which the first core layer is formed.

12. The semiconductor integrated optical device according to claim 1, wherein the first optical function device region functions as a semiconductor laser.

13. The semiconductor integrated optical device according to claim 1, wherein the second optical function device region functions as a connecting waveguide.

14. The semiconductor integrated optical device according to claim 8, wherein the third optical function device region functions as a modulator.
